(19) United States
(12) Patent Application Publication
(10) Pub. No.: US 2025/0192512 A1
(43) Pub. Date: Jun. 12, 2025

(54) LIGHT-EMITTING DEVICE, RANGING DEVICE, AND ONBOARD DEVICE

(71) Applicant: SONY GROUP CORPORATION, TOKYO (JP)

(72) Inventors: GYONGSOK SONG, TOKYO (JP); YASUTAKA HIGA, TOKYO (JP); TATSUYA MATOU, TOKYO (JP); SHUHEI YAMAGUCHI, TOKYO (JP); HIDEKI WATANABE, TOKYO (JP); RINTARO KODA, TOKYO (JP)

(21) Appl. No.: 18/843,843

(22) PCT Filed: Feb. 17, 2023
(86) PCT No.: PCT/JP2023/005714

§ 371 Date: Sep. 4, 2024

(30) Foreign Application Priority Data
Mar. 15, 2022 (JP) 2022-040170

(51) Int. Cl. H01S 5/042; G01S 7/481; G01S 17/931; H01S 5/183

(52) U.S. Cl. CPC H01S 5/04256; H01S 5/04254; H01S 5/18377; G01S 7/4815; G01S 17/931

(57) ABSTRACT

For example, the effective light-emitting area of a light-emitting part is maximized as much as possible. A light-emitting device including a unit structure formed by a plurality of units of emission, wherein the unit of emission includes a first structure including a first multilayer mirror, a second structure including a second multilayer mirror, and an active layer disposed between the first structure and the second structure, the unit structure includes a first electrode electrically connected between the first structures of the different units of emissions and a second electrode electrically connected between the second structures of different units of emission, and the number of combination of the first electrode and the second electrode connected to the predetermined unit of emission in the predetermined unit structure is one.

### TECHNICAL FIELD

The present disclosure relates to a light-emitting device, a ranging device, and an onboard device.

### BACKGROUND ART

PTL 1 and PTL 2 listed below disclose a laser array chip in which a plurality of surface-emitting laser elements are two-dimensionally arranged and two wires connected to the surface-emitting laser elements are formed on the same substrate. PTL 3 discloses a technique of improving the integration degree of elements by sharing the contact of one polarity among a plurality of elements.

### CITATION LIST

### Patent Literature

[PTL 1] JP 2000-12973 A
[PTL 2] JP 2000-22274 A
[PTL 3] JP 2021-48208 A

### SUMMARY

### Technical Problem

In this field, a light-emitting part desirably has a maximum effective light-emitting area.

An object of the present disclosure is to provide a light-emitting device, a ranging device, and an onboard device that can maximize the effective light-emitting area of a light-emitting part.

### Solution to Problem

The present disclosure is, for example,
a light-emitting device including a unit structure formed by a plurality of units of emission,
wherein the unit of emission includes:
a first structure including a first multilayer mirror;
a second structure including a second multilayer mirror; and
an active layer disposed between the first structure and the second structure,
the unit structure includes:
a first electrode electrically connected between the first structures of the different units of emission, and
a second electrode electrically connected between the second structures of the different units of emission, and
a number of combination of the first electrode and the second electrode connected to the predetermined unit of emission in the predetermined unit structure is one.

The present disclosure may be a ranging device including the foregoing light-emitting device.

The present disclosure may be an onboard device including the foregoing ranging device.

### BRIEF DESCRIPTION OF DRAWINGS

FIG. 1 illustrates a configuration example of a surface emitting laser according to an embodiment.

FIG. 2 is a diagram to be referred to in a description of the configuration example of the light-emitting device according to the embodiment,

FIG. 3 is a diagram to be referred to in a description of the configuration example of the light-emitting device according to the embodiment.

FIG. 4 is a diagram to be referred to in a description of an effect that can be obtained by the embodiment.

FIG. 5 is a diagram to be referred to in a description of an effect that can be obtained by the embodiment,

FIG. 6 is an explanatory drawing of a modification example.

FIG. 7 is an explanatory drawing of a modification example.

FIG. 8 is an explanatory drawing of a modification example.

FIG. 9 is an explanatory drawing of a modification example.

FIG. 10 is a block diagram of a schematic configuration example of a vehicle control system.

FIG. 11 is an explanatory diagram showing an example of the installation positions of a vehicle external information detector and imaging units.

### DESCRIPTION OF EMBODIMENTS

An embodiment of the present disclosure will be described below with reference to the drawings. The description will be made in the following order.

### EMBODIMENT

### Modification Examples

### Application Example

The embodiment described below is a preferred specific example of the present disclosure and the contents of the present disclosure are not limited to the embodiment. In the following description, constituent elements having substantially the same functional configurations are indicated by the same reference numerals, and a redundant description thereof is omitted as appropriate. In order to avoid a complicated illustration, only a part of the configuration may be denoted by reference numerals or the drawings may be simplified or scaled up/down. For ease of description, vertical and horizontal directions are defined, but the contents of the present disclosure are not limited to these directions.

### EMBODIMENT

### [Surface Emitting Laser]

A surface emitting laser (hereinafter referred to as a surface emitting laser 10 as appropriate) according to the present embodiment is a vertical cavity surface emitting laser (VCSEL) The surface emitting laser 10 (one surface emitting laser) corresponds to an example of a unit of emission. A plurality of surface emitting lasers form a surface-emitting laser array. A light-emitting device according to the present disclosure includes one or more surface emitting lasers.

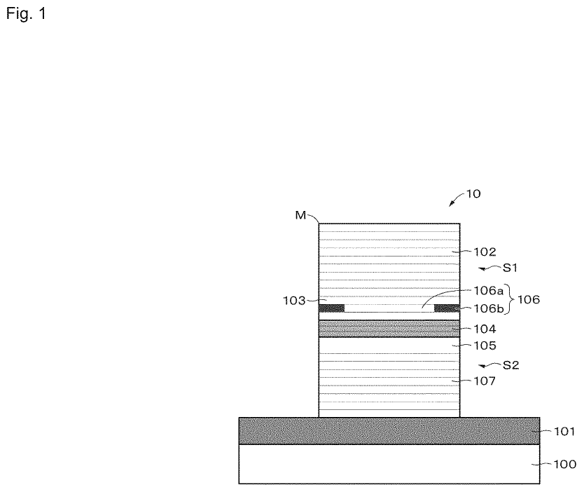

FIG. 1 illustrates a sectional configuration example of the surface emitting laser 10 according to the embodiment. As illustrated in FIG. 1, the surface emitting laser 10 includes a substrate 100 as an example of a first substrate, a first structure S1 including a first multilayer mirror 102, a second structure S2 including a second multilayer mirror 107, and an active layer 104 disposed between the first and second structures S1 and S2. A first electrode and a second electrode are electrically connected to the surface emitting laser 10 (specifically described later). The surface emitting laser 10 is driven by, for example, a laser driver (not illustrated). For example, the substrate 100 is disposed on the opposite side of the second multilayer mirror 107 from the active layer 104.

The first structure S1 includes a first clad layer 103 disposed between the first multilayer mirror 102 and the active layer 104. In the first clad layer 103, an oxidation confinement layer 106 is provided.

The second structure S2 further includes a contact layer 101 disposed between the substrate 100 and the second multilayer mirror 107 and a second clad layer 105 disposed between the second multilayer mirror 107 and the active layer 104.

A light-emitting part (resonator) has a configuration including the first and second structures S1 and S2 and the active layer 104.

Apart of the first structure S1, the second structure S2, and the active layer 104 constitute a mesa M having the top portion in the first structure S1. The mesa M has a configuration including, for example, the first multilayer mirror 102, the active layer 104, the first clad layer 103 including the oxidation confinement layer 106, the second multilayer mirror 107, and the second clad layer 105. The mesa M has, for example, a substantially cylindrical shape and may have other shapes such as a substantially elliptic cylinder, a polygonal column, a truncated cone, an elliptic cone, or a pyramid. The height direction of the mesa M substantially agrees with the stacking direction (the vertical direction in FIG. 1) of the surface emitting laser 10, The diameter of the mesa M is, for example, 1 μm to 500 μm. The substrate 100 is disposed opposite to the front side of the mesa M (for example, the front side of the top portion).

For example, the surface emitting laser 10 emits a laser beam from the back side (underside) of the substrate 100, In other words, the surface emitting laser 10 is, for example, a back-side emission VCSEL.

### (Substrate)

The substrate 100 includes, for example, an insulating semiconductor substrate (e.g., a GaAs substrate), The back side (underside) of the substrate 100 is coated with a thin film as an AR film, in which light to be emitted from the surface emitting laser 10 (light with an oscillation wavelength λ from the surface emitting laser 10) is not absorbed or hardly absorbed.

The contact layer 101 includes, for example, a semiconductor layer (e.g., a GaAs layer) of a first conductivity type (e.g., n-type). The contact layer 101 has a higher impurity doping concentration and a lower resistance than the substrate 100.

### (First Multilayer Mirror)

The first multilayer mirror 102 is, for example, a semiconductor multilayer mirror. A multilayer mirror is also called a distributed Bragg reflector. A semiconductor multilayer mirror, which is a kind of semiconductor multilayer mirror (distributed Bragg reflector), has a low absorbance, a high reflectivity, and high conductivity. Specifically, the first multilayer mirror 102 is, for example, a semiconductor multilayer mirror of a second conductivity type (e.g., p-type) and has a structure in which several kinds (e.g., two kinds) of semiconductor layers having different refractive indexes are alternately stacked with an optical thickness equal to one quarter of the oscillation wavelength. The reflectivity of the first multilayer mirror 102 is set slightly higher than that of the second multilayer mirror 107.

### (First Clad Layer)

The first clad layer 103 contains, for example, an AlGaAs compound semiconductor of the second conductivity type (e.g., p-type).

### (Active Layer)

The active layer 104 has, for example, a quantum well structure including a barrier layer, which contains an AlGaAs compound semiconductor, and a quantum well layer. The quantum well structure may be a single quantum-well structure (QW structure) or a multiple quantum-well structure (MQW structure). In the active layer 104, a region corresponding to a non-oxidizing region 106a (a current passage portion, described later) of the oxidation confinement layer 106 serves as an emitting region. The active layer 104 may have multiple QW structures or multiple MQW structures that are stacked with a tunnel junction interposed therebetween.

### (Second Clad Layer)

The second clad layer 105 contains, for example, an AlGaAs compound semiconductor of the first conductivity type (e.g., n-type).

### (Oxidation Confinement Layer)

The oxidation confinement layer 106 includes, for example, the AlGaAs non-oxidizing region 106a and an oxidizing region 106b containing an AlGaAs oxide (e.g., Al₂O₃) around the non-oxidizing region 106a. The non-oxidizing region 106a acts as a current/light passage portion while the oxidizing region 106b acts as a current/light confinement portion.

### (Second Multilayer Mirror)

The second multilayer mirror 107 is, for example, a semiconductor multilayer mirror. Specifically, the second multilayer mirror 107 is, for example, a semiconductor multilayer mirror of the first conductivity type (e.g., n-type) and has a structure in which several kinds (e.g., two kinds) of semiconductor layers having different refractive indexes are alternately stacked with an optical thickness equal to one quarter of the oscillation wavelength. The refractive index layers of the second multilayer mirror 107 contain an AlGaAs compound semiconductor of the first conductivity type (e.g., n-type).

### [Light-Emitting Device]

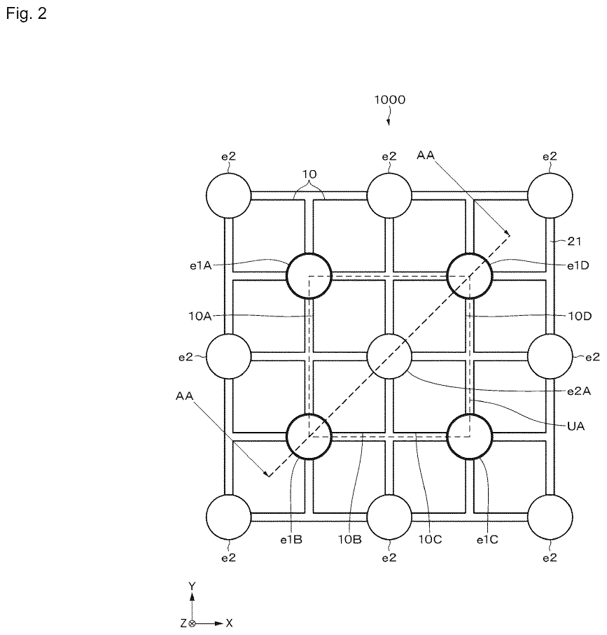

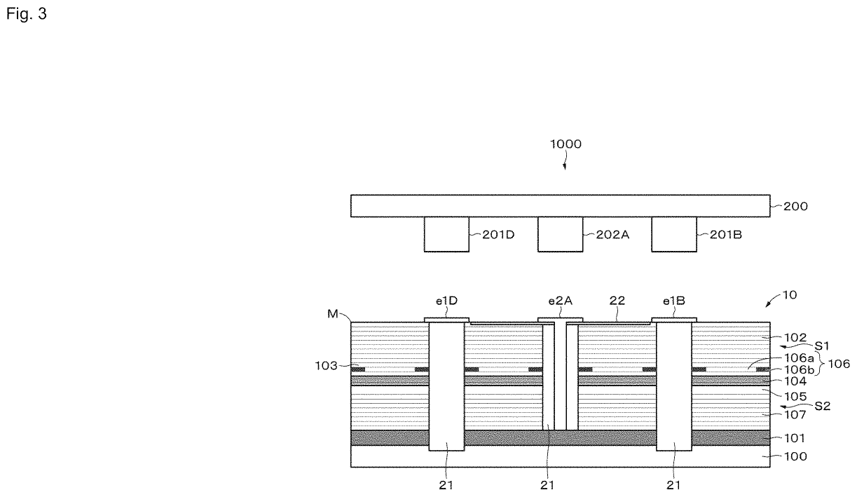

Referring to FIGS. 2 and 3, a light-emitting device (hereinafter referred to as a light-emitting device 1000 as appropriate) including the multiple surface emitting lasers 10 will be described below. FIG. 2 is a plan view of the light-emitting device 1000. FIG. 3 is a cross-sectional view of the light-emitting device 1000 taken along cutting-plane line AA-AA of FIG. 2.

As illustrated in FIG. 2, the light-emitting device 1000 includes a configuration in which the four surface emitting lasers 10 are placed in X direction (horizontal direction) indicated as an example of a first direction and the four surface emitting lasers 10 are placed in Y direction (vertical direction) indicated as an example of a second direction orthogonal to the first direction. As a matter of course, the number of surface emitting lasers 10 is not limited to 16 and a different number of surface emitting lasers 10 may be provided. Moreover, the surface emitting lasers 10 are not always arranged in a matrix form and may be arranged in a honeycomb pattern. The surface emitting lasers 10 are insulated from one another by a high-resistance region part 21.

The light-emitting device 1000 has a unit structure formed by a plurality of units of emission. As illustrated in FIG. 2, for example, a unit structure UA is formed by the two surface emitting lasers 10 placed in X direction and the two surface emitting lasers 10 placed in Y direction. Specifically, the unit structure UA is formed by surface emitting lasers 10A, 10B, 10C, and 10D. In FIG. 2, the location of the unit structure UA is surrounded by dots. The unit structure UA in the present embodiment is conceptual and may be shaped into a physically detectable frame. FIG. 2 illustrates the single unit structure UA alone. In reality, the light-emitting device 1000 includes multiple unit structures UA.

First and second electrodes e1 and e2 are electrically connected to the surface emitting laser 10. The first electrode e1 acts as an anode electrode and is electrically connected to, for example, the anode (positive electrode) of a laser driver. The second electrode e2 acts as a cathode electrode and is electrically connected to, for example, the cathode (negative electrode) of a laser driver.

As illustrated in FIG. 3, the first electrode e1 (for example, a first electrode e1D) is partially connected to the first structure S1 (for example, the surface of the top portion of the first structure S1). For example, a part of the first electrode e1 is in contact with an exposed surface around the mesa M of the first structure S1. The first electrode e1 is insulated from the second structure S2, the substrate 100, and the contact layer 101 by the high-resistance region part 21.

For example, the first electrode e1 has a laminated structure (e.g., a three-layer structure) in which a first contact metal, a first pad metal, and a first plating metal are stacked in this order. The illustration of the configuration is omitted.

For example, the first contact metal is configured such that a Ti layer, a Pt laver, and an Au layer are stacked in this order from the vicinity of the substrate 100 or the contact layer 101. The thickness of the Ti layer is, for example, 2 nm to 100 nm. The thickness of the Pt layer is, for example, 2 nm to 300 nm. The thickness of the Au layer is, for example, 100 nm to 500 nm. The first contact metal is not limited to the foregoing layer structure if the first contact metal is electrically connected to, for example, the first structure S1.

For example, the first pad metal has a laminated structure (e.g., a three-layer structure) in which a Ti layer, a Pt layer, and an Au layer are sequentially stacked from the vicinity of the first contact metal. The thickness of the Ti layer is, for example, 2 nm to 100 nm. The thickness of the Pt layer is, for example, 2 nm to 300 nm. The thickness of the Au layer is, for example, 100 nm to 1000 nm. The first pad metal may be configured differently from the foregoing layer structure.

The first plating metal is configured with, for example, an Au layer. The thickness of the Au layer is, for example, 1000 nm to 5000 nm. For example, if a break of the first pad metal can be prevented with a lower resistance by increasing the thickness of the first pad metal, the first plating metal may be absent or another configuration may be provided instead.

The second electrode e2 (e.g., a second electrode e2A) is connected to the contact layer 101 via, for example, a trench structure. The second electrode e2 is insulated from the first structure S1 by the high-resistance region part 21. Moreover, an insulating portion (insulating layer) 22 is provided between the second electrode e2 and the top portion of the mesa M (the top portion of the first structure S1). The second electrode e2 and the mesa M are insulated from each other by the insulating portion 22. The first electrode e1 and the second electrode e2 are about 1 to 400 μm smaller in diameter than the mesa M.

For example, the second contact metal is configured such that a Ti layer, a Pt layer, and an Au layer are stacked in this order from the vicinity of the substrate 100 or the contact layer 101. The thickness of the Ti layer is, for example, 2 nm to 100 nm. The thickness of the Pt layer is, for example, 2 nm to 300 nm. The thickness of the Au layer is, for example, 100 nm to 500 nm. The second contact metal is not limited to the foregoing layer structure if the second contact metal is connected to, for example, the contact layer 101.

For example, the second pad metal has a laminated structure (e.g., a three-layer structure) in which a Ti layer, a Pt layer, and an Au layer are sequentially stacked from the vicinity of the second contact metal. The thickness of the Ti layer is, for example, 2 nm to 100 nm. The thickness of the Pt layer is, for example, 2 nm to 300 nm. The thickness of the Au layer is, for example, 100 nm to 1000 nm. The second pad metal may have a configuration other than the foregoing layer structure.

The second plating metal is configured with, for example, an Au layer. The thickness of the Au layer is, for example, 1000 nm to 5000 nm. For example, if a break of the second pad metal can be prevented with a lower resistance by increasing the thickness of the second pad metal, the second plating metal may be absent or another configuration may be provided instead.

The insulating portion 22 is, for example, an insulating film made of SiO2, SiN, and SiON. The film thickness of the insulating portion 22 is, for example, 10 to 300 nm.

Efficient oscillation of the light-emitting device 1000 requires a current confinement structure. In the present embodiment, the high-resistance region part 21 is formed by, for example, ion implantation. However, the method is not limited if current confinement is enabled. Current confinement methods include, for example, QWI in which a carrier is confined by providing a bandgap energy difference between a point of an aperture diameter and the outside by Ga vacancy diffusion, and embedding TJ. Alight confinement method may be a method of increasing the effective refractive index of an aperture portion by providing a step. A photocurrent confinement method may be a method of providing an AlOₓlayer (oxidation confinement layer) in any one of a DBR and the clad layer.

As illustrated in FIG. 3, a second substrate 200 is disposed on the top surface of the light-emitting device 1000 (the near side of the drawing in FIG. 2). On the second substrate 200, a first wiring portion 201 and a second wiring portion 202 are disposed. The first wiring portion 201 is electrically connected to the first electrode e1. The second wiring portion 202 is electrically connected to the second electrode e2. In the example of FIG. 3, a first wiring portion 201B is connected to a first electrode e1B and a first wiring portion 201D is connected to the first electrode e1). Moreover, a second wiring portion 202A is connected to a second electrode e2A. Current injected to the first electrode e1 through the first wiring portion 201 and is injected to the second electrode e2 through the second wiring portion 202.

As illustrated in FIGS. 2 and 3, the first electrode e1 (e.g., a first electrode e1A, the first electrode e1B, a first electrode e1C, and the first electrode e1D) disposed inside one end is electrically connected between the first structures S1 of the different surface emitting lasers 10. Moreover, the second electrode e2 (e.g., the second electrode e2A) is electrically connected between the contact layers 101 (second structures S2) of the different surface emitting lasers 10. The number of combination of the first electrode e1 and the second electrode e2 connected to the predetermined surface emitting laser 10 in a predetermined unit structure is one.

For example, the predetermined unit structure UA includes the four surface emitting lasers 10A to 10D. The outer edge of the unit structure UA is substantially rectangular. The second electrode e2A is disposed around a substantially central portion of the unit structure UA. The first electrodes e1 included in the unit structure UA are disposed around the second electrode e2A. For example, the four first electrodes e1A to e1D are disposed at four points around the second electrode e2A (around the corners of the unit structure UA).

As illustrated in FIG. 2, the surface emitting lasers 10 to which the first electrode e1 is electrically connected serve as the surface emitting lasers 10 in different unit structures. For example, the first electrode e1A is electrically connected to the surface emitting laser 10A in the unit structure UA and is also electrically connected to the surface emitting laser 10 that is located outside the unit structure IA and may form another unit structure. The second electrode e2A is electrically connected to all the surface emitting lasers 10 (surface emitting lasers 10A to 10D) in the unit structure UA. Furthermore, in the present embodiment, the single second electrode e2 is provided in the unit structure UA.

According to the configuration, the number of combination of the first electrode e1 and the second electrode e2 connected to the predetermined surface emitting laser 10 in a predetermined unit structure is one. For example, the number of combination of the first electrode and the second electrode to be connected to the surface emitting laser 10A in the unit structure UA is one, that is, a combination of the first electrode e1A and the second electrode e2A. Moreover, the number of combination of the first electrode and the second electrode to be connected to the surface emitting laser 10B in the unit structure UA is one, that is, a combination of the first electrode e1B and the second electrode e2A, Furthermore, the number of combination of the first electrode and the second electrode to be connected to the surface emitting laser 10C in the unit structure UA is one, that is, a combination of the first electrode e1C and the second electrode e2A. In addition, the number of combination of the first electrode and the second electrode to be connected to the surface emitting laser 10D in the unit structure UA is one, that is, a combination of the first electrode e1D and the second electrode e2A.

### [Operation of Light-Emitting Device]

An operation example of the light-emitting device 1000 will be described below. For example, a current that is supplied from the anode side of a laser driver and flows from the first electrode e1 (anode electrode) passes through the first multilayer mirror 102, is confined by the oxidation confinement layer 106, and is injected into the active layer 104. At this point, the active layer 104 emits light, and the light reciprocates between the first and second multilayer mirrors 102 and 107 while being amplified by the active layer 104 and confined by the oxidation confinement layer 106. The light is emitted as a laser beam from the back side of the substrate 100 when the oscillation conditions are satisfied. The current having passed through the active layer 104 reaches the second electrode e2 (cathode electrode) through the second clad layer 105 and the second multilayer mirror 107 and is passed from the second electrode e2 to, for example, the cathode side of the laser driver.

### [Manufacturing Method Example of Light-Emitting Device]

An example of a method for manufacturing the light-emitting device 1000 will be described below. As an example, the multiple surface emitting lasers 10 are simultaneously generated on a single wafer, which is a base material of the substrate 100, according to a semiconductor manufacturing method using semiconductor manufacturing equipment. The integrally generated surface emitting lasers 10 are then separated to obtain chips of the surface emitting lasers 10.

First, the substrate 100 made of GaAs is prepared. Thereafter, on the surface of the substrate 100, for example, the contact layer 101, the second multilayer mirror 107, the second clad layer 105, the active layer 104, the first clad layer 103, and the first multilayer mirror 102 are epitaxially grown in this order from the substrate 100 at, for example, a growth temperature of 605° C. according to, for example, MOCVD (Metal Organic Chemical Vapor Deposition).

When MOCVD is performed, for example, trimethyl gallium ((CH₃)₃Ga) is used as a source gas of gallium, trimethyl aluminum ((CH₃)₃Al)) is used as a source gas of aluminum, trimethyl indium ((CH₃)₃In) is used as a source gas of indium, and trimethyl arsenide ((CH₃)₃As) is used as a source gas of As. Furthermore, for example, monosilane (SiH₄) is used as a source gas of silicon, and carbon tetrabromide (CBr₄) is used as a source gas of carbon.

Subsequently, a resist coating film is formed on the first multilayer mirror 102, and the high-resistance region part 21 is formed by ion implantation. At this point, the depth of implantation is set up to, for example, the underside of the contact layer 101. The resist coating film is then removed.

Subsequently, a resist coating film is formed on the first multilayer mirror 102, and a trench structure is formed in the high-resistance region part 21 by dry etching, for example, reactive ion etching (RIE). At this point, the depth of etching is set up to, for example, the inside of the contact layer 101. The resist coating film is then removed.

Subsequently, a p-contact metal is formed on the emitting region by using, for example, the lift-off method. At this point, the size of the contact metal is about 1 to 300 μm smaller than the size of the emitting region. The contact metal is formed by vacuum deposition or sputtering.

Subsequently, an insulating film is formed on the surface by using, for example, vacuum deposition or sputtering. Thereafter, the insulating film on the contact metal and a part of the contact layer 101 is removed by etching using, for example, RIE and a solution containing hydrogen fluoride.

Subsequently, a contact metal is formed on the contact layer 101 and trench side walls. The contact metal is formed by vacuum deposition or sputtering. Thereafter, a pad metal is formed on the contact metal on the contact layer by, for example, the lift-off method. The pad metal is formed by vacuum deposition or sputtering. Thereafter, a plating metal is formed on the pad metal. The plating metal is formed on the pad metal.

The light-emitting device 1000 is produced by the above-mentioned process.

### [Effect Obtained by Present Embodiment]

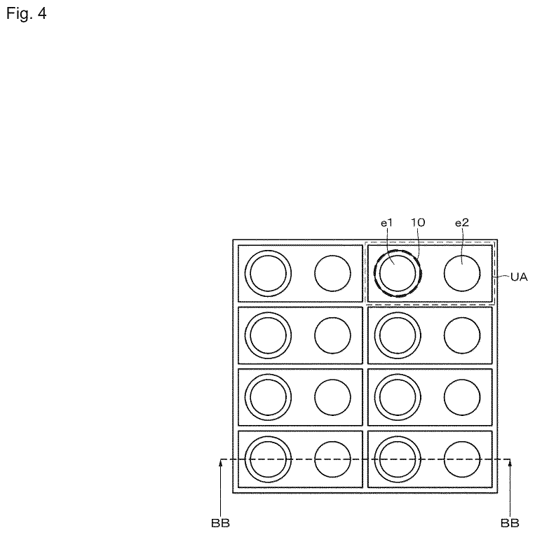

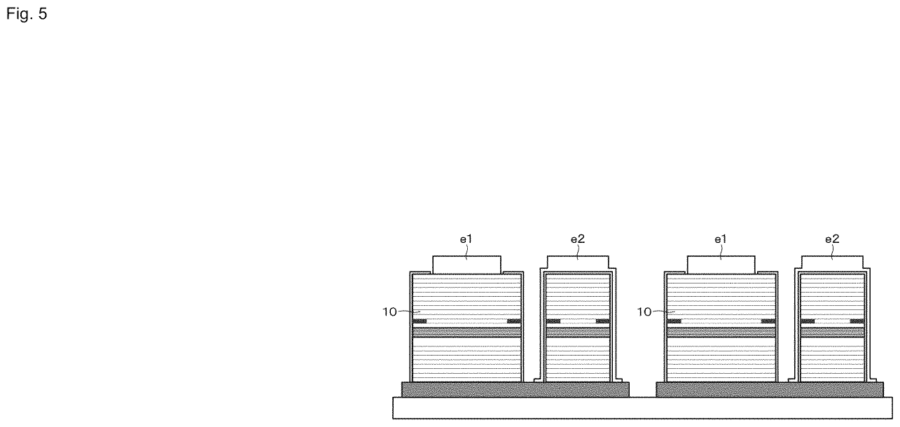

An example of an effect obtained by present embodiment will be described below. FIG. 4 is a plan view of a conventional light-emitting device, FIG. 5 illustrates a sectional configuration example of the light-emitting device taken along cutting-plane line BB-BB of FIG. 4. Conventionally, a wiring region (the first electrode e1 and the second electrode e2) needs to be provided for each predetermined unit of emission (e.g., the surface emitting laser 10), so that the ratio of a light-emitting area to an overall element may disadvantageously decrease. However, according to the present embodiment, the first electrode e1 and the second electrode e2 are shared by a plurality of units of emission. This can minimize a reduction in light-emitting area and maximize an effective light-emitting area. Moreover, the first electrode e1 and the second electrode e2 do not need to be formed on the periphery of a unit of emission (the surface emitting lasers 10 in the present embodiment). In short, downsizing can be achieved in addition to sharing of the electrodes.

Moreover, the first electrode e1 and the second electrode e2 can be disposed near the surface emitting laser 10, achieving a lower impedance than in wire bonding connection.

Furthermore, an interval between the first electrode e1 and the second electrode e2 can be secured, enabling manufacturing of the light-emitting device without using an advanced packaging technique.

Moreover, according to the present embodiment, individual driving can be performed in units of emission. Generally, sharing of electrodes involves difficulty in individual driving because light is emitted from all the emission regions connected to the electrodes. According to the present embodiment, for example, in FIG. 2, current is injected between the first electrode e1A and the second electrode e2A, so that light is emitted only from the surface emitting laser 10A without light emission from the surface emitting lasers 10B to 10D and other surface emitting lasers 10 in the same unit structure UA. In other words, individual driving can be performed.

A high current density can be obtained by enabling individual driving in units of emission, achieving higher laser intensity. For example, when the light-emitting device is applied to a ranging device, a unit of emission from which a laser beam is reflected cannot be identified on the reception side depending upon the ranging system. Thus, units of emission for light emission need to be changed in a time-sharing manner. In this case, according to the present embodiment, individual driving can be performed in units of emission, and laser intensity can be improved. Thus, units of emission for light emission can be changed in a time-sharing manner, and a laser beam can be emitted to a ranging object at long range as well as short range. In short, a dynamic range for ranging can be increased, thereby improving the performance of a ranging device.

### Modification Examples

The embodiment of the present disclosure was specifically described above. The contents of the present disclosure are not limited to the above-described embodiment and can be modified in various ways on the basis of the technical spirit of the present disclosure.

### Modification Example 1

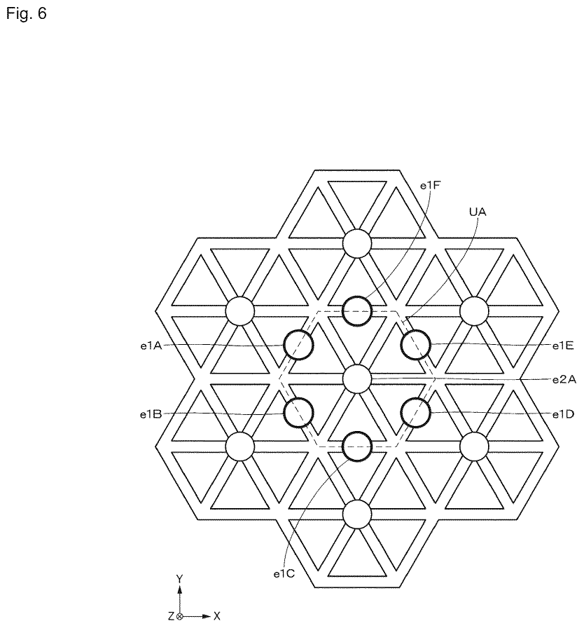

Units of emission in plan view may have other shapes such as a circle and a triangle in addition to a rectangle. Moreover, a unit structure may include units of emission like polygons. For example, as illustrated in FIG. 6, the unit structure TA may have a configuration including six triangular units of emission in plan view. In the case of the configuration, the unit structure UA has an outer edge shaped like a polygon (e.g., a hexagon). The second electrode e2 is disposed and connected at a vertex near the center of each unit of emission. The six first electrodes e1 (the first electrodes e1A to e1F) are disposed around the second electrode e2, and the first electrodes e1 are connected to the respective units of emission. The configuration in FIG. 6 can obtain the same effect as the embodiment.

### Modification Example 2

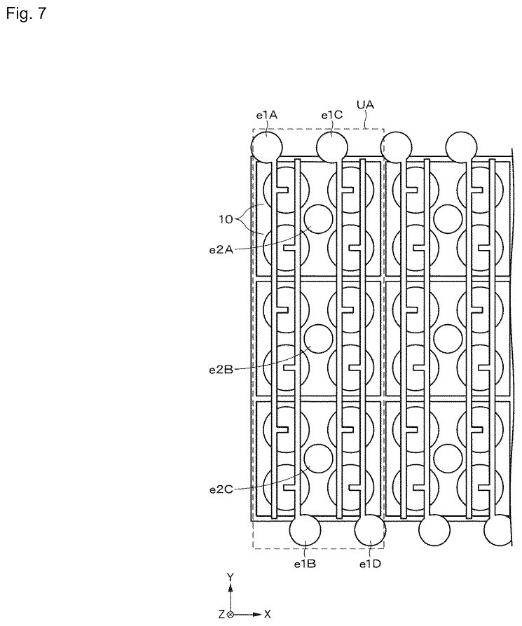

In the embodiment, individual driving is performed for each unit of emission. Individual driving may be performed for each set of units of emission. FIG. 7 is a plan view illustrating a light-emitting device according to the present modification example. The unit structure UA according to the present modification example includes the two surface emitting lasers 10 placed in X direction and the six surface emitting lasers 10 placed in Y direction, that is, the twelve surface emitting lasers 10 in total.

For example, the first electrode e1 is shaped like a belt and is electrically connected to predetermined ones of the six surface emitting lasers 10 placed in Y direction. More specifically, the first electrode e1 is connected to every second one of the surface emitting lasers 10 (three surface emitting lasers 10 in this example) disposed in the extending direction of the first electrode e1. For example, the first electrode e1A is electrically connected to the first, the third, and the fifth surface emitting lasers 10 from the far side in Y direction among the six surface emitting lasers 10 disposed in the leftmost column in FIG. 7 (a protrusion extending from the belt-like shape in X direction indicates an electrical connection in FIG. 7). The first electrode e1B is electrically connected to the second, the fourth, and the sixth surface emitting lasers 10 from the far side in Y direction among the six surface emitting lasers 10 disposed in the leftmost column in FIG. 7. The first electrode e1C is electrically connected to the first, the third, and the fifth surface emitting lasers 10 from the far side in Y direction among the six surface emitting lasers 10 disposed in the second column from the left in FIG. 7. The first electrode e1D is electrically connected to the second, the fourth, and the sixth surface emitting lasers 10 from the far side in Y direction among the six surface emitting lasers 10 disposed in the second column from the left in FIG. 7.

For example, the sixteen surface emitting lasers 10 are grouped into four blocks, each including the four surface emitting lasers 10 (the four surface emitting lasers 10 placed like a square), and the second electrode e2 is electrically connected to the four surface emitting lasers 10 constituting the block. For example, the second electrode e2A is electrically connected to all the four surface emitting lasers 10 constituting the first block from the far side in Y direction. The second electrode e2B is electrically connected to all the four surface emitting lasers 10 constituting the second block from the far side in Y direction. The second electrode e2C is electrically connected to all the four surface emitting lasers 10 constituting the third block from the far side in Y direction.

The first electrode e1 and the second electrode e2 are electrically connected to the surface emitting lasers 10 in, for example, a pattern similar to that of the embodiment.

As in the present modification example, the surface emitting lasers 10 to which the first electrode e1 is electrically connected may be the surface emitting lasers 10 located in the same unit structure unlike in the embodiment where the surface emitting lasers 10 are located in units of emission in the different unit structures. Moreover, the first electrode e1 may be shaped like a belt.

### Modification Example 3

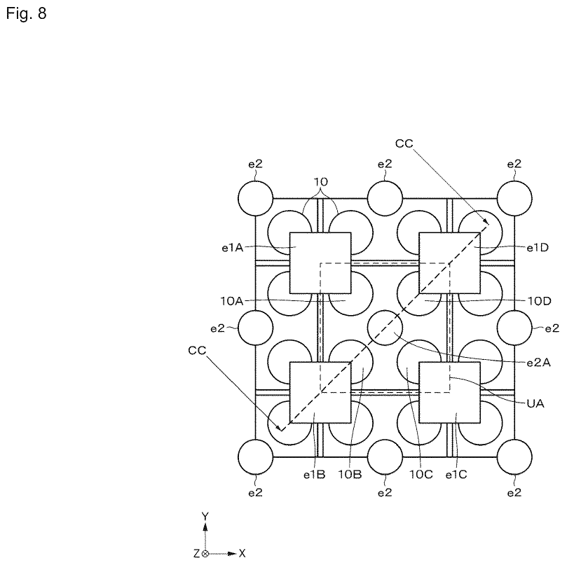

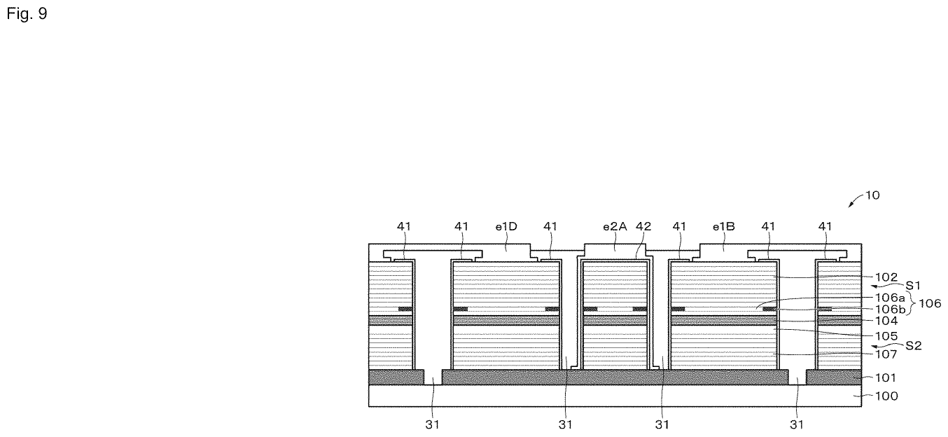

FIG. 8 is a plan view of a light-emitting device according to modification example 3. FIG. 9 illustrates a cross section of the light-emitting device taken along cutting-plane line CC-CC of FIG. 8. The first electrode e1 is connected to the top portion of the mesa M. On the mesa M where the first electrode e1 is connected, an insulating film 41 is formed on a portion other than a portion to which the first electrode e1 is connected. The second electrode e2 is connected to the contact layer 101. An insulating layer 42 is formed between the mesa M and the second electrode e2, An insulating material 31 is provided between the mesas M. The insulating material 31 ensures current confinement. As described above, a current confinement structure may be a structure other than an ion implantation structure. As illustrated in FIGS. 8 and 9, for example, the current confinement structure may be provided with mesas.

### Other Modification Examples

The substrates included in the surface emitting lasers according to the embodiment and modification examples may be, for example, a substrate containing GaN or a substrate containing InP. In other words, materials for laser oscillation wavelength bands (e.g., 200 nm to 2000 nm) can be selected as appropriate.

In the embodiment and modification examples, the components of the first multilayer mirror and the second multilayer mirror may include, for example, an insulating material and a metal as well as a semiconductor.

In the embodiment and the modification examples, the laminated electrode structure of the first electrode e1 and the second electrode e2 does not need to include all the contact metal, the pad metal, and the plating metal. For example, the plating metal may be absent in the structure. Alternatively, metals of other materials including Cu may be stacked on the plating metal.

In the embodiment and the modification examples, if the first electrode e1 and the second electrode e2 are configured to be shared when being formed as modules, the connection points of the electrodes may be located opposite to those of the embodiment.

In the embodiment and the modification examples, the electrode structure may be an intra-cavity structure. Moreover, in the foregoing embodiment, the substrate 100 may be an n-type substrate. In this case, a layer having an insulting function may be provided between the contact layer 101 and the second multilayer mirror 107.

In the embodiment and the modification examples, the shape of the emission region in plan view is not limited to a circle and may be, for example, a triangle, a rectangle, or an ellipse.

The present disclosure can be implemented by a ranging device using a light-emitting device, an onboard device having the ranging device, and the form of a method or the like as well as a light-emitting device. The effects described in the present specification are merely examples and are not intended as limiting, and other effects may be obtained.

The present disclosure can also be configured as follows:

(1)

A light-emitting device including a unit structure formed by a plurality of units of emission,
wherein the unit of emission includes:
a first structure including a first multilayer mirror;
a second structure including a second multilayer mirror; and
an active layer disposed between the first structure and the second structure, the unit structure includes:
a first electrode electrically connected between the first structures of the different units of emission, and
a second electrode electrically connected between the second structures of the different units of emission, and
a number of combination of the first electrode and the second electrode connected to the predetermined unit of emission in the predetermined unit structure is one.
   (2)

The light-emitting device according to (1), wherein the first electrodes are disposed around the second electrode.

(3)

The light-emitting device according to (1) or (2), wherein the units of emission to which the first electrode is electrically connected are units of emission in different unit structures.

(4)

The light-emitting device according to (3), wherein the plurality of units of emission are disposed along a first direction and a second direction orthogonal to the first direction in the unit structure.

(5)

The light-emitting device according to (4), wherein the two units of emission are disposed along the first direction and the two units of emission are disposed along the second direction.

(6)

The light-emitting device according to (2), wherein the plurality of units of emission are disposed like polygons in the unit structure.

(7)

The light-emitting device according to (1) or (2), wherein the units of emission to which the first electrode is electrically connected are units of emission in the same unit structure.

(8)

The light-emitting device according to (7), wherein the first electrode is shaped like a belt.

(9)

The light-emitting device according to (8), wherein the first electrode is connected to every second one of the units of emission disposed in an extending direction of the first electrode.

(10)

The light-emitting device according to any one of (1) to (9), wherein the first electrode is provided on the front side of the first structure, and the second electrode is provided on the front side of the first structure with an insulating layer interposed between the front side of the first structure and the second electrode.

(11)

The light-emitting device according to (10), further including a first substrate disposed opposite to the front side, wherein a laser beam is emitted from the first substrate.

(12)

The light-emitting device according to (10) or (11), further including a second substrate on the front side of the first structure, wherein the second substrate is provided with a first wiring portion electrically connected to the first electrode and a second wiring portion electrically connected to the second electrode.

(13)

The light-emitting device according to any one of (1) to (12), wherein a number of the second electrode in the unit structure is one.

(14)

The light-emitting device according to (13), wherein the second electrode is electrically connected to all the units of emission in the unit structure.

(15)

A ranging device including the light-emitting device according to any one of (1) to (14).

(16)

An onboard device including the ranging device according to (15).

### Application Example

The technique according to the present disclosure can be applied to various products. For example, the technique according to the present disclosure may be implemented as an apparatus mounted on any kind of mobile body such as an automobile, an electric vehicle, a hybrid electric vehicle, a motorcycle, a bicycle, a personal mobility, an airplane, a drone, a ship, a robot, a construction machine, or an agricultural machine (tractor).

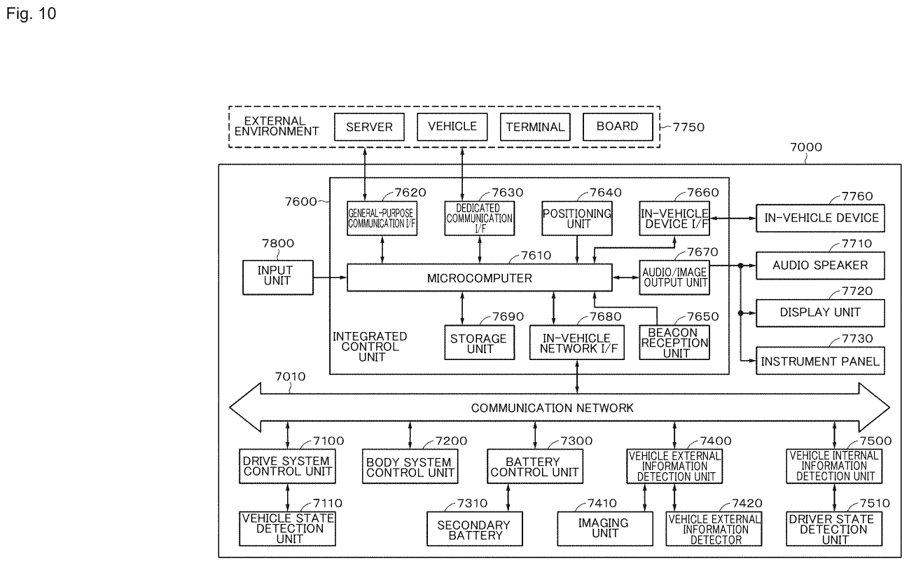

FIG. 10 is a block diagram illustrating a schematic configuration example of a vehicle control system 7000 that is an example of a mobile body control system to which the technique according to the present disclosure is applicable. The vehicle control system 7000 includes a plurality of electronic control units connected via a communication network 7010. In the example illustrated in FIG. 10, the vehicle control system 7000 includes a drive system control unit 7100, a body system control unit 7200, a battery control unit 7300, a vehicle external information detection unit 7400, a vehicle internal information detection unit 7500, and an integrated control unit 7600. The communication network 7010 connecting the plurality of control units may be, for example, an in-vehicle communication network compliant with any standards such as CAN (Controller Area Network), LIN (Local Interconnect Network), LAN (Local Area Network), and FlexRay (registered trademark).

Each control unit includes a microcomputer that performs arithmetic processing according to various programs, a storage unit that stores programs executed by the microcomputer, parameters used for various arithmetic operations, and the like, and a drive circuit that drives various control target devices. Each control unit includes a network I/F for performing communication with another control unit via the communication network 7010, and includes a communication I/F for performing communication with devices or sensors inside or outside the vehicle through wired communication or wireless communication. In FIG. 10, a microcomputer 7610, a general-purpose communication I/F 7620, a dedicated communication I/F 7630, a positioning unit 7640, a beacon reception unit 7650, an in-vehicle device I/F 7660, an audio/image output unit 7670, an in-vehicle network I/F 7680, and a storage unit 7690 are shown as functional configurations of the integrated control unit 7600. The other control units also include a microcomputer, a communication I/F, a storage unit, and the like.

The drive system control unit 7100 controls the operations of devices related to the drive system of the vehicle according to various programs. For example, the drive system control unit 7100 functions as a control device for a driving force generation device for generating a vehicle driving force of an internal combustion engine or a drive motor, a driving force transmission mechanism for transmitting the driving force to wheels, a steering mechanism for adjusting a steering angle of the vehicle, a braking device that generates a braking force of the vehicle. The drive system control unit 7100 may have a function as a control device, for example, an ABS (Antilock Brake System) or ESC (Electronic Stability Control).

A vehicle state detection unit 7110 is connected to the drive system control unit 7100. The vehicle state detection unit 7110 includes, for example, at least one of a gyro sensor that detects an angular velocity of an axial rotation motion of a vehicle body an acceleration sensor that detects an acceleration of a vehicle, and a sensor that detects an operation amount of an acceleration pedal, an operation amount of a brake pedal, a steering angle of a steering wheel, an engine rotation number or a rotation speed of wheels, and the like. The drive system control unit 7100 performs arithmetic processing using a signal input from the vehicle state detection unit 7110, to control an internal combustion engine, a drive motor, an electric power steering device, a brake device, and the like.

The body system control unit 7200 controls operations of various devices equipped in the vehicle body in accordance with various programs. For example, the body system control unit 7200 functions as a control device of a keyless entry system, a smart key system, a power window device, or various lamps such as a head lamp, a back lamp, a brake lamp, a turn indicator, and a fog lamp. In this case, radio waves emitted from a portable device in place of a key or signals of various switches can be input to the body system control unit 7200. The body system control unit 7200 receives inputs of radio waves or signals and controls a door lock device, a power window device, and a lamp of the vehicle.

The battery control unit 7300 controls a secondary battery 7310 which is a power supply source of a driving motor in accordance with various programs. For example, information such as a battery temperature, a battery output voltage, or a remaining capacity of a battery is input from a battery device including the secondary battery 7310 to the battery control unit 7300. The battery control unit 7300 performs arithmetic processing using such a signal and performs temperature adjustment control of the secondary battery 7310 or control of a cooling device equipped in the battery device.

The vehicle external information detection unit 7400 detects information outside the vehicle in which the vehicle control system 7000 is mounted. For example, at least one of an imaging unit 7410 and a vehicle external information detector 7420 is connected to the vehicle external information detection unit 7400. The imaging unit 7410 includes at least one of a ToF (Time Of Flight) camera, a stereo camera, a monocular camera, an infrared camera, and other cameras. The vehicle external information detector 7420 includes at least one of, for example, an environmental sensor detecting present weather or atmospheric phenomena and a surrounding information detection sensor detecting other vehicles, obstacles, pedestrians, and the like around a vehicle where the vehicle control system 7000 is mounted.

The environmental sensor may be, for example, at least one of a raindrop sensor that detects rainy weather, a fog sensor that detects fog, a sunshine sensor that detects the degree of sunshine, and a snow sensor that detects snowfall. The surrounding information detection sensor may be at least one of an ultrasonic sensor, a radar device, and a LIDAR (Light Detection and Ranging, Laser Imaging Detection and Ranging) device. The imaging unit 7410 and the vehicle external information detector 7420 may be included as independent sensors or devices or may be included as a device in which a plurality of sensors or devices are integrated.

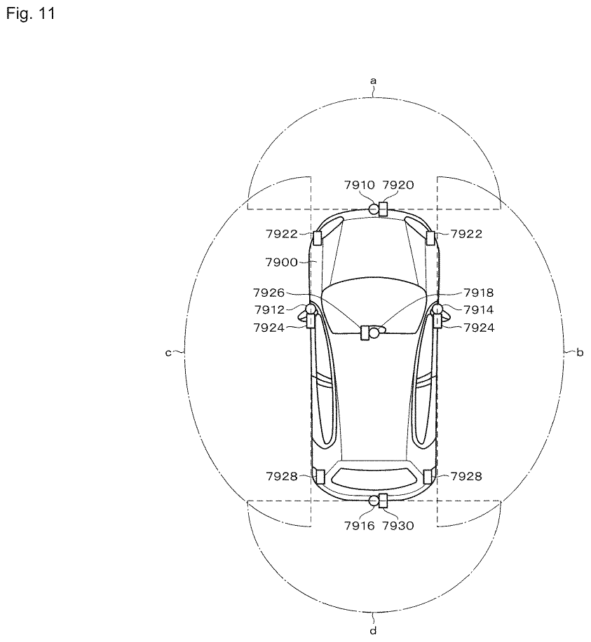

FIG. 11 illustrates an example of installation positions of the imaging unit 7410 and the vehicle external information detector 7420, Imaging units 7910, 7912, 7914, 7916, and 7918 are provided, for example, at at least one of a front nose, side mirrors, a rear bumper, a back door, and an upper part of a windshield in a vehicle cabin of the vehicle 7900. The imaging unit 7910 included in the front nose and the imaging unit 7918 included in the upper part of the windshield in the vehicle cabin mainly acquire an image in front of the vehicle 7900. The imaging units 7912 and 7914 included in the side mirrors mainly acquire images of the sides of the vehicle 7900. The imaging unit 7916 included in the rear bumper or the back door mainly acquires an image of the rear of the vehicle 7900. The imaging unit 7918 included in the upper part of the windshield in the vehicle cabin is mainly used for detection of a vehicle ahead, a pedestrian, an obstacle, a traffic light, a traffic sign, a lane, or the like.

In FIG. 11, an example of shooting ranges of the respective imaging units 7910, 7912, 7914, and 7916 is illustrated. An imaging range a indicates an imaging range of the imaging unit 7910 provided on the front nose, imaging ranges b and c indicate imaging ranges of the imaging units 7912 and 7914 provided on the side mirrors, and an imaging range d indicates an imaging range of the imaging unit 7916 provided on the rear bumper or the back door. For example, a bird's-eye view image of the vehicle 7900 as viewed from above can be obtained when the image data captured by the imaging units 7910, 7912, 7914, and 7916 are superimposed.

The vehicle external information detectors 7920, 7922, 7924, 7926, 7928, and 7930 provided on the front, rear, sides, corners, and an upper part of the windshield in the vehicle 7900 may be, for example, ultrasonic sensors or radar devices. The vehicle external information detectors 7920, 7926, and 7930 provided on the front nose, rear bumper, back door, and upper part of the windshield in the vehicle 7900 may be, for example, LIDAR devices. These vehicle external information detectors 7920 to 7930 are mainly used for detection of vehicles ahead, pedestrians, or obstacles or the like.

The description will be continued with reference to FIG. 10 again. The vehicle external information detection unit 7400 causes the imaging unit 7410 to capture an image of the outside of the vehicle and receives the captured image data. Furthermore, the vehicle external information detection unit 7400 receives detection information from the connected vehicle external information detector 7420, When the vehicle external information detector 7420 is an ultrasonic sensor, a radar device, or a LIDAR device, the vehicle external information detection unit 7400 transmits ultrasonic waves, electromagnetic waves, or the like, and receives information on received reflected waves. The vehicle external information detection unit 7400 may perform object detection processing or distance detection processing for a person, a vehicle, an obstacle, a sign, or a character on a road surface on the basis of the received information. The vehicle external information detection unit 7400 may perform environment recognition processing for recognizing rainfall, fog, road surface situation, or the like on the basis of the received information. The vehicle external information detection unit 7400 may calculate a distance to an object outside the vehicle on the basis of the received information.

Further, the vehicle external information detection unit 7400 may perform image recognition processing or distance detection processing for recognizing a person, a vehicle, an obstacle, a sign, a character on a road surface, or the like on the basis of the received image data. The vehicle external information detection unit 7400 may perform processing such as distortion correction or alignment on the received image data, and combine image data captured by the different imaging units 7410 to generate a bird's-eye view image or a panoramic image. The vehicle external information detection unit 7400 may perform viewpoint conversion processing using the image data captured by the different imaging units 7410.

The vehicle internal information detection unit 7500 detects information inside the vehicle. For example, a driver state detection unit 7510 that detects a driver's state is connected to the vehicle internal information detection unit 7500. The driver state detection unit 7510 may include a camera that images a driver, a biological sensor that detects biological information of the driver, or a microphone that collects a sound in the vehicle. The biosensor is provided on, for example, a seat surface or a steering wheel, and detects biological information about a passenger on a seat or a driver holding the steering wheel. The vehicle internal information detection unit 7500 may calculate a degree of fatigue or a degree of concentration of the driver on the basis of detection information input from the driver state detection unit 7510, and may determine whether the driver is asleep. The vehicle internal information detection unit 7500 may perform processing such as noise canceling processing on the collected audio signal.

The integrated control unit 7600 controls overall operations in the vehicle control system 7000 according to various programs. An input unit 7800 is connected to the integrated control unit 7600, The input unit 7800 is implemented by a device that can be operated for input by a passenger, for example, a touch panel, a button, a microphone, a switch, or a lever. Data obtained by recognizing voice inputted through a microphone may be inputted to the integrated control unit 7600. The input unit 7800 may be, for example, a remote control device using infrared rays or other radio waves, or may be an externally connected device such as a mobile phone or a PDA (Personal Digital Assistant) corresponding to an operation on the vehicle control system 7000. The input unit 7800 may be, for example, a camera. In this case, the passenger can input information by gesture. Alternatively data obtained by detecting a motion of a wearable device worn by the passenger may be input. Furthermore, the input unit 7800 may include, for example, an input control circuit that generates an input signal on the basis of information input by the passenger or the like using the input unit 7800 and outputs the input signal to the integrated control unit 7600. The passenger or the like inputs various types of data to the vehicle control system 7000 or instructs a processing operation by operating the input unit 7800.

The storage unit 7690 may include a ROM (Read Only Memory) that stores various programs to be executed by a microcomputer, and a RAM (Random Access Memory) that stores various parameters, calculation results, or sensor values or the like. The storage unit 7690 may be implemented by, for example, a magnetic storage device such as an HDD (Hard Disc Drive), a semiconductor storage device, an optical storage device, or a magneto-optical storage device.

The general-purpose communication I/F 7620 is a general-purpose communication I/F that mediates communication with various devices present in an external environment 7750. The general-purpose communication I/F 7620 may have, implemented therein, a cellular communication protocol such as GSM (Global System of Mobile communications) (registered trademark), WiMAX (registered trademark), LTE (Long Term Evolution) (registered trademark), or LTE-A (LTE-Advanced), or other wireless communication protocols such as wireless LAN (also referred to as Wi-Fi (registered trademark)) or Bluetooth (registered trademark). The general-purpose communication I/F 7620 may be connected to, for example, a device (for example, an application server or a control server) present on an external network (for example, the Internet, a cloud network, or a business-specific network) via a base station or an access point. The general-purpose communication I/F 7620 may be connected to terminals (for example, the terminals of the driver, pedestrians, or shops, or MTC (Machine Type Communication) terminals) near the vehicle by using, for example, P2P (Peer To Peer) technology.

The dedicated communication I/F 7630 is a communication I/F supporting a communication protocol formulated for the purpose of use in a vehicle. The dedicated communication I/F 7630 may implement, for example, a standard protocol such as a WAVE (Wireless Access in Vehicle Environment) that is a combination of IEEE802.11p of a lower layer and IEEE1609 of an upper layer, a DSRC (Dedicated Short Range Communications), or a cellular communication protocol. The dedicated communication I/F 7630 typically performs V2X communications as a concept including one or more of vehicle to vehicle communications, vehicle to infrastructure communications, vehicle to home communications, and vehicle to pedestrian communications.

The positioning unit 7640 receives, for example, a GNSS signal from a global navigation satellite system (GNSS) satellite (for example, a GPS signal from a global positioning system (GPS) satellite), executes positioning, and generates position information including a latitude, longitude, and altitude of the vehicle. The positioning unit 7640 may specify a current position by exchanging signals with a wireless access point, or may acquire position information from a terminal such as a mobile phone, PHS, or smartphone having a positioning function.

The beacon reception unit 7650 receives radio waves or electromagnetic waves transmitted from a radio station or the like installed on a road, and acquires information such as a current position, traffic jam, no throughfare, or required time. A function of the beacon reception unit 7650 may be included in the above-described dedicated communication I/F 7630.

The in-vehicle device I/F 7660 is a communication interface that mediates connections between the microcomputer 7610 and various in-vehicle devices 7760 present in the vehicle. The in-vehicle device I/F 7660 may establish a wireless connection using wireless communication protocols such as a wireless LAN, Bluetooth (registered trademark), NFC (Near Field Communication), and WUSB (Wireless USB). Furthermore, the in-vehicle device I/F 7660 may establish a wired connection of for example, a USB (Universal Serial Bus), HDMI (registered trademark) (High-Definition Multimedia Interface), or MHL (Mobile High-definition Link) via a connection terminal (not illustrated) (and a cable if necessary). The in-vehicle device 7760 may include, for example, at least one of a mobile device or wearable device of an occupant and an information device carried in or attached to the vehicle. Further, the in-vehicle device 7760 may include a navigation device that searches for a route to an arbitrary destination. The in-vehicle device I/F 7660 exchanges control signals or data signals with the in-vehicle devices 7760.

The in-vehicle network I/F 7680 is an interface that mediates communications between the microcomputer 7610 and the communication network 7010. The in-vehicle network I/F 7680 transmits and receives signals or the like in conformity with a predetermined protocol supported by the communication network 7010.

The microcomputer 7610 of the integrated control unit 7600 controls the vehicle control system 7000 in accordance with various programs based on information acquired through at least one of the general-purpose communication I/F 7620, the dedicated communication I/F 7630, the positioning unit 7640, the beacon reception unit 7650, the in-vehicle device I/F 7660, and the in-vehicle network I/F 7680. For example, the microcomputer 7610 may calculate control target values for a driving force generation device, a steering mechanism, or a braking device on the basis of acquired information on the inside and outside of the vehicle, and output control commands to the drive system control unit 7100. For example, the microcomputer 7610 may perform cooperative control for the purpose of implementing the functions of ADAS (Advanced Driver Assistance System), the functions including vehicle collision avoidance or impact mitigation, follow-up traveling based on an inter-vehicle distance, vehicle speed maintenance driving, a vehicle collision warning, and a vehicle lane departure warning. The microcomputer 7610 may perform coordinated control for automated driving in which a vehicle travels autonomously regardless of an operation of a driver, by controlling, for example, a driving force generation device, a steering mechanism, or a braking device on the basis of acquired surrounding information on the vehicle.

The microcomputer 7610 may generate three-dimensional distance information between the vehicle and objects such as surrounding structures or people based on information acquired via at least one of the general-purpose communication I/F 7620, the dedicated communication I/F 7630, the positioning unit 7640, the beacon reception unit 7650, the in-vehicle device I/F 7660, and the in-vehicle network I/F 7680 and may generate local map information including surrounding information of a present position of the vehicle. The microcomputer 7610 may predict a danger such as collision of the vehicle, approach of a pedestrian, or entry into a traffic prohibition road based on the acquired information and may generate a warning signal. The warning signal may be, for example, a signal for generating a warning sound or turning on a warning lamp.

The audio/image output unit 7670 transmits at least one of audio and image output signals to an output device capable of visually or audibly notifying a passenger of the vehicle or the outside of the vehicle of information. In the example of FIG. 10, an audio speaker 7710, a display unit 7720, and an instrument panel 7730 are illustrated as output devices. The display unit 7720 may include, for example, at least one of an on-board display and a head-up display. The display unit 7720 may have an AR (Augmented Reality) display function. The output device may be other devices such as a headphone, a wearable device such as a glasses-type display worn by a passenger, a projector, and a lamp. When the output device is a display device, the display device visually displays results obtained through various processes performed by the Microcomputer 7610 or information received from another control unit in various formats such as text, images, tables, and graphs. When the output device is a sound output device, the sound output device converts an audio signal formed by reproduced sound data, acoustic data, or the like into an analog signal and outputs the analog signal auditorily.

In the example illustrated in FIG. 10, at least two control units connected via the communication network 7010 may be integrated as one control unit.

Alternatively, each control unit may be configured of a plurality of control units. Further, the vehicle control system 7000 may include another control unit (not illustrated), Further, in the above description, the other control unit may have some or all of functions of any one of the control units. That is, predetermined arithmetic processing may be performed by any one of the control units as long as information is transmitted and received via the communication network 7010. Similarly, a sensor or device connected to any one of the control units may be connected to the other control unit, and a plurality of control units may transmit or receive detection information to and from each other via the communication network 7010.

In the foregoing vehicle control system 7000, the light-emitting device of the present disclosure is applicable to, for example, the vehicle external information detector.

### REFERENCE SIGNS LIST

10 Surface emitting laser
100 Substrate
101 Contact layer
102 First multilayer mirror
103 First clad layer
104 Active layer
105 Second clad layer
106 Oxidation confinement layer
107 Second multilayer mirror
UA Unit structure
e1 First electrode
e2 Second electrode
S1 First structure
S2 Second structure

1. A light-emitting device comprising a unit structure formed by a plurality of units of emission,
wherein the unit of emission includes:
a first structure including a first multilayer mirror;
a second structure including a second multilayer mirror; and
an active layer disposed between the first structure and the second structure,
the unit structure includes:
a first electrode electrically connected between the first structures of the different units of emission, and
a second electrode electrically connected between the second structures of the different units of emission, and
a number of combination of the first electrode and the second electrode connected to the predetermined unit of emission in the predetermined unit structure is one.

2. The light-emitting device according to claim 1, wherein the first electrodes are disposed around the second electrode.

3. The light-emitting device according to claim 1, wherein the units of emission to which the first electrode is electrically connected are units of emission in different unit structures.

4. The light-emitting device according to claim 3, wherein the plurality of units of emission are disposed along a first direction and a second direction orthogonal to the first direction in the unit structure.

5. The light-emitting device according to claim 4, wherein the two units of emission are disposed along the first direction and the two units of emission are disposed along the second direction.

6. The light-emitting device according to claim 2, wherein the plurality of units of emission are disposed like polygons in the unit structure.

7. The light-emitting device according to claim 1, wherein the units of emission to which the first electrode is electrically connected are units of emission in the same unit structure.

8. The light-emitting device according to claim 7, wherein the first electrode is shaped like a belt.

9. The light-emitting device according to claim 8, wherein the first electrode is connected to every second one of the units of emission disposed in an extending direction of the first electrode.

10. The light-emitting device according to claim 1, wherein the first electrode is provided on a front side of the first structure, and the second electrode is provided on the front side of the first structure with an insulating layer interposed between the front side of the first structure and the second electrode.

11. The light-emitting device according to claim 10, further comprising a first substrate disposed opposite to the front side, wherein a laser beam is emitted from the first substrate.

12. The light-emitting device according to claim 10, further comprising a second substrate on the front side of the first structure, wherein the second substrate is provided with a first wiring portion electrically connected to the first electrode and a second wiring portion electrically connected to the second electrode.

13. The light-emitting device according to claim 1, wherein a number of the second electrode in the unit structure is one.

14. The light-emitting device according to claim 13, wherein the second electrode is electrically connected to all the units of emission in the unit structure.

15. A ranging device comprising the light-emitting device according to claim 1.

16. An onboard device comprising the ranging device according to claim 15.
